(19) United States
(12) Patent Application Publication
(10) Pub. No.: US 2008/0210953 A1
(43) Pub. Date: Sep. 4, 2008

(54) Luminaire with a Plurality of Light-Emitting Diodes in Decentralized Arrangement

(75) Inventors: Gerald Ladstatter, Klaus (AT); Anton Mundle, Satteins (AT)

Correspondence Address: MARSHALL, GERSTEIN & BORUN LLP, 233 S. WACKER DRIVE, SUITE 6300, SEARS TOWER, CHICAGO, IL, 60606, US

(73) Assignee: Zumtobel Lighting GmbH, Dombirn (AT)

(21) Appl. No.: 11/994,222

(22) PCT Filed: May 15, 2006
(86) PCT No.: PCT/EP2006/004571

§ 371 Date: Mar. 3, 2008

(30) Foreign Application Priority Data
Jun. 29, 2005 (DE) 10 2005 030 374.9

(51) Int. Cl. H01L 33/00

(52) U.S. Cl. 257/88; 257/E33.067

(57) ABSTRACT

A luminaire with a plurality of light-emitting diodes in a decentralized arrangement. To improve the light emission pattern issued by the luminaire, the emission region defined by the light guide emission ends is smaller than the arrangement region defined by the totality of the light-emitting diodes.

The invention concerns a luminaire in accordance with the preamble of the claim 1.

A luminaire of this kind is known and therefore state of the art. With this known luminaire the light source is formed by a plurality of light-emitting diodes in decentralized arrangement. The decentralized arrangement of the light-emitting diodes may be required for a variety of reasons. On the one hand, it can be predetermined for structural reasons. On the other hand, the decentralized arrangement of the light-emitting diodes may arise from a necessity for an adequate cooling of the light-emitting diodes. Namely, light-emitting diodes produce heat and they are sensitive to heat. This applies in particular to a plurality of light-emitting diodes which are arranged with spacings from each other, in order on the one hand to keep the mutual heating within limits and on the other hand through this to achieve cooling by heat dissipation to the surroundings.

Due to the arrangement of the light-emitting diodes with mutual spacings a non-uniform light emission pattern is provided for the common light source with a plurality of points of light or cones of light produced by the light-emitting diodes, between which due to the spacings dark regions are present, which is undesired.

The invention is based on the object of, with a luminaire of the kind indicated in the introduction, improving the light emission pattern, in particular to keep it small, preferably creating a luminaire having light-emitting diodes with a light irradiation as concentrated as possible.

This object is achieved by the features of the claim 1. Advantageous developments of the invention are indicated in the dependent claims.

The invention is based on the insight that the light emission pattern of the known luminaire, which is in need of improvement, is determined by the spacings between the light-emitting diodes, which may be present for a variety of reasons, e.g. a sufficient cooling, and that the desired improvement can be attained by a reduction of the spacings. To this extent improvement could e.g. be achieved by an improvement of the cooling which, however, is complex and expensive.

On the other hand, the configuration in accordance with the invention primarily aims not to improve the cooling and also not to reduce the spacings between the light-emitting diodes, but to direct the light produced by the light-emitting diodes to a light emission region which has a lesser transverse dimension than the transverse dimension of the decentralized arrangement of the light-emitting diodes.

The light emission region is preferably defined by the emitting ends of light guides which conduct the light of the light-emitting diodes to the emission region.

Thereby the invention is the further based on the insight that the light emission surfaces of the light guides can without doubt be made more proximate to each other and e.g. can be positioned to an emission region of reduced transverse dimension or to a common emission surface of reduced transverse dimension, because light coupled into a light guide is non-critical with regard to heat. A desired improvement therefore consists in a reduction of the transverse dimension of the emission region, whereby also in the configuration in accordance with the invention spacings can be present between the light emission surfaces of the light guides. Since however these light emission surfaces are heat independent, the spacings can be dimensioned to be so small that an optimal light emission is attained in the emission region. It is an advantageous embodiment to lead the light produced by the light-emitting diodes through the light guides to a common light emission surface in the region of which there are no spacings between individual light emission surfaces of the light guides. This can be effected e.g. by a light mixing device which is also suitable for a mixing of different light colours, which can be delivered by different light guides.

Within the scope of the invention the emission region of reduced transverse dimension, in the case of an elongate luminaire or in the case of a compact luminaire, can be formed in the form of a row or two rows running beside one another or at a spacing from one another or in form of a solid area or a ring area. This also applies for the light-emitting diodes. The light-emitting diodes can also, e.g. for an elongate luminaire, be arranged on the two sides of the longitudinal middle plane in one or two rows.

Thereby it is advantageous for the purpose of a further improvement of a compact luminaire form to arrange the emission region in accordance with the invention concentrically with the decentralized arrangement of the light-emitting diodes.

Thereby, the emission region can be arranged substantially in a plane with the light-emitting diodes, through which among other things a flat manner of construction is achieved. The emission region can, with regard to the light-emitting diodes also be offset downwardly, which is attainable e.g. by light guides extending in arc shape. A light emission region offset downwardly is also excellently suitable for a combination with two reflectors laterally facing each other or a pot-shaped or ring-shaped reflector. In both cases the light-emitting diodes can be arranged in decentralized arrangement above the reflectors, whilst the emission surface can be arranged offset to below the reflection region of the reflectors.

Below advantageous configurations of the invention will be explained in more detail with reference to several exemplary embodiments and the drawings. There is shown:

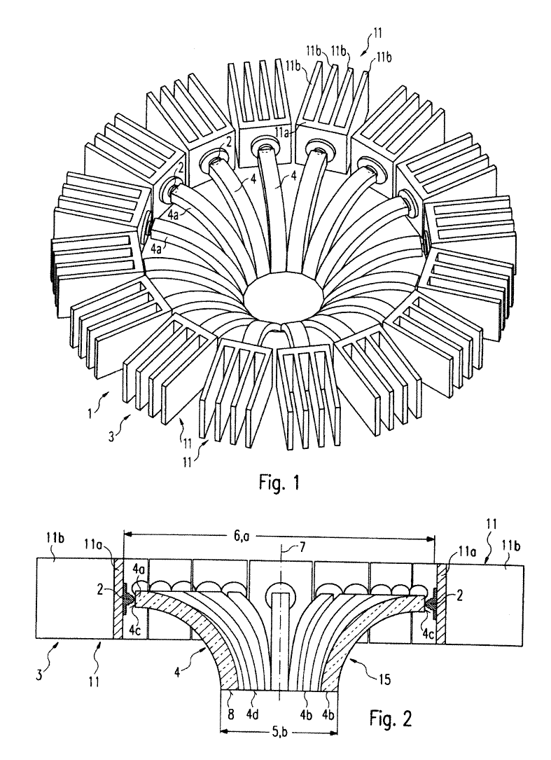

FIG. 1 a luminaire in accordance with the invention in a perspective view from above;

FIG. 2 the luminaire in the vertical section;

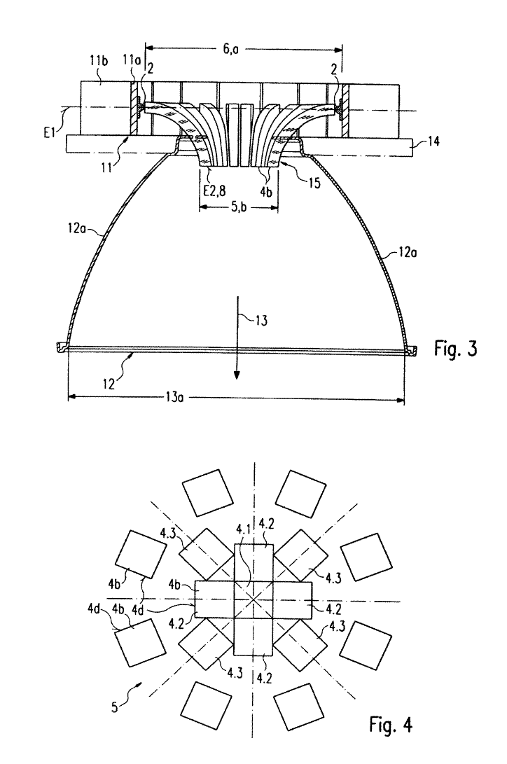

FIG. 3 the luminaire according to FIG. 2 with a reflector;

FIG. 4 an emission region of a luminaire in accordance with the invention in the line of sight onto the emission surfaces of several light guides;

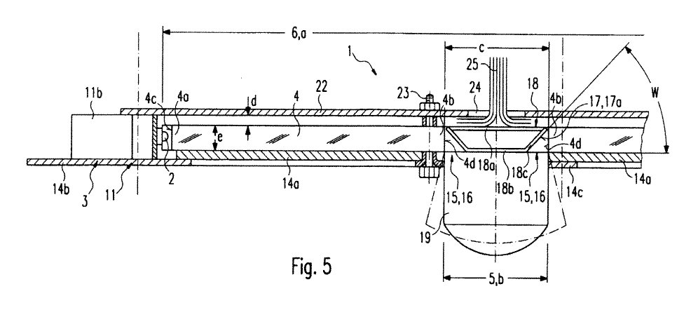

FIG. 5 a luminaire in accordance with the invention in modified configuration in vertical section.

The main components of the luminaire, designated by 1 as a whole, are a plurality light-emitting diodes 2 which in a decentralized arrangement form a light source, a cooling device 3 for the light-emitting diodes 2 and a plurality of light guides 4 of light permeable, e.g. crystal-clear material which in the case of the embodiment in accordance with FIGS. 1 and 2 are of the same form, but could however also be constituted with different forms, and a light emission region 5 into which the light guides 4 extend and are located with their light emission ends 4b.

Since the light guides 4 can be formed in optional shapes and also lengths, the emission region 5 and the light source region 6 formed by the light-emitting diodes 2 can also be arranged at optional spacings and positions relative to each other.

In the embodiment the light-emitting diodes 2 and the emission ends 4b are arranged in each case in a horizontal plane E1, E2, wherein these planes E1, E2 can be arranged in a common plane or transversely offset to one another. In the embodiment the plane E2 of the emission region 5 is offset downwardly with respect to the plane E1 of the light source region 6, i.e. offset towards the room to be illuminated. Thereby the light source region 6 and the emission region 5 may be arranged concentrically with respect to a vertical middle axis 7 of the luminaire 1, whereby they in addition may extend at right-angles to the vertical middle axis 7.

The expression decentralized arrangement for the light-emitting diodes 2 means that that these can be arranged not concentrated or compactly, e.g. closely neighbouring one another, but with spacings from each other on the complete surface region of the light source region 6. The light-emitting diodes 2 are in the present embodiments located at the perimeter of the light source region 6 and they are thus arranged ring-like, whereby they can be arranged in an optional ring form, in the case of the embodiments in accordance with FIGS. 1 to 3 in a round ring form.

Against this, the light emitting ends 4b are arranged at lesser spacings from each other and therefore more compactly arranged as the light incidence ends 4a of the light guides 4 or the light-emitting diodes 2, which are arranged before the light incidence ends 4a and are arranged in their preferably flat light incidence surfaces 4c. Therefore the cross-sectional dimension a of the light source region 6 is substantially larger than the cross-sectional dimension b of the emission region 5, in which the emission ends 4b may bear on one another or also have a spacing from each other which is as small as possible. Thereby the preferably also flat light emission surfaces 4d of the light guides 4 may be arranged in the associated plane E2.

The cross-sectional sizes and forms of the light guides 4 can be chosen as desired. In the embodiment the light guides 4 have a quadrilateral cross-sectional form, whereby they may bear laterally on one another in their preferably round ring form. Thereby the light emission surfaces 4d form a common light emission surface 8 which is in the embodiment in accordance with FIGS. 1 to 3 of round ring form, but can be however also of other form, and is interrupted b small seams between the light guides 4 which scarcely disturb a desired uniform light emission and uniform light pattern due to the slight distance between the light guides 4.

Since light-emitting diodes 2 on the one hand produce heat and are on the other hand sensitive to heat, there is needed in the operation of the luminaire 1 a cooling of the light-emitting diodes 2. In the present embodiments the cooling device 3 is provided, the effectiveness of which is based on heat dissipation and heat emission from a common or a plurality of cooling bodies 11. The at least one cooling body 11 is at the same time carrier for the associated light-emitting diode 2 or the light-emitting diodes 2. In the present embodiments a cooling body 11 is associated with every light-emitting diode 2, which consists of a vertical carrier wall 11a and one or a plurality of preferably vertical cooling fins 11b projecting outwardly from the outside thereof. Through this an efficient cooling is ensured due to the large surface and self-acting automatic upward lift of the warmed air.

The light-emitting diodes 2 are in each case arranged and fastened on the inner sides of the carrier walls 11a, e.g. adhered, wherein their emission directions are directed towards one another or radially inwardly, wherein they radiate radially inwardly into the light incidence ends 4a lying opposite them.

The embodiment according to FIG. 3, for which the same or comparable parts are provided with the same reference signs, the above-described luminaire 1 is supplemented by a reflector 12, the lateral reflector walls 12a of which, with respect to the downwardly directed main emission direction 13 of the luminaire 1, extend mirror-image-wise in arc shape and thereby degressively divergently, and with their free edges 12b bound a main emission opening 13a.

For the fastening of the cooling bodies 11 and the reflector 12 there may serve a schematically represented, e.g. plate-shaped, base part 14 to which the cooling bodies 11 and the reflector 12 are fastened.

In the present embodiment in accordance with FIGS. 1 to 3 in which the luminaire 1 is a dome shaped luminaire, the reflector walls 12a lying opposite each other are formed by common and in horizontal cross-section ring-like, in particular round, dome shaped peripheral wall.

The invention is suitable however also for elongate luminaires, with light-emitting diodes 2 arranged on the left and on the right of a vertical middle plane. With such a configuration the reflector walls 12a can be formed by profiles extending in the longitudinal direction of the luminaire 1. With such an elongate luminaire the light guides 4 are not arranged ray-like but they extend transversely of the longitudinal direction of the luminaire, wherein they may extend parallel to each other. With such a configuration the light-emitting diodes 2, the light incidence ends 4a and the light emission ends 4b are preferably located in longitudinally running rows.

In the above-described embodiment the light guides 4 form a light directing device 15 which serves to deflect the light in another direction, in the case of the embodiment to deflect it by 90° downwardly and thereby concentrically.

FIG. 4 shows a light emission region 5 in which the light emission ends 4b or their light emission surfaces 4d are arranged in different positions and spacings from each other. In the centre, there may bear on the here flat side surfaces of a central, preferably quadratic light guide 4.1 four further light guides 4.2 on the side faces thereof, through which there is provided a cross-shaped arrangement of these five light guides 4.1, 4.2. In the region of the clearances between the light guides 4.2 there can be arranged light guides 4.3 rotated by about 45°, which are arranged rotated with respect to the light guides 4.1, 4.2 by 45°. Furthermore, further light guides 4.4 can be arranged distributed on the perimeter, which are arranged preferably with respect to the light guides 4.3 to the outside and offset in the circumferential direction.

With the above-described arrangement of the light emission ends 4b there results an outwardly reducing number of light emission surfaces 4d. Therefore the light emitted by the above-described light emission region 5 decreases, with regard to its light density, to the outside, when there is involved light of the same color, e.g. bright or white light. However, the arrangement is also suitable for light-emitting diodes which emit light of different color.

The embodiment according to FIG. 5, for which the same or comparable parts also are provided with the same reference sign, makes a flat luminaire construction possible and it differs in substance in that the light guides 4 extend straight or horizontally inwardly and at a preferably central spacing c from each other. In this spacing region c there is arranged another light directing device 15 which deflects the light downwardly so that it is emitted downwardly. In addition, a light mixing device 16 is provided which mixes the light bundles emitted by the light guides 4. Through this the light is mixed over the seam regions between the light bundles of the light guides 4, so that light is emitted downwardly with a uniform light pattern at a common light emission surface 17.

In the case of the embodiment, the light directing device 15 and the light mixing device 16 are combined with one another and formed by an oblique surface 17a running obliquely downwardly with respect to the light emission end 4b, which oblique surface may be in the case of the embodiment of a round luminaire 1 a downwardly convergent conical surface, which includes with the vertical middle axis 7 an upwardly open acute angle W which preferably may be about 45°. The oblique surface 17a can be formed by the peripheral surface of a component 18, trapeziform in cross-section, that has e.g. an upper wall 18a and a lower wall 18b which are connected with the upper and lower edges of a conical section shaped peripheral wall 18c.

Under the light directing device 15 and/or light mixing device 16 there may be provided a light influencing body 19 for altering the light emission. The light influencing body 19 may be formed e.g. by a light guide which is prismatic, in particular cylindrical, in the vertical, of light permeable, e.g. crystal-clear, material, the underside of which may have a shape deviating from a flat surface, e.g. the form of a preferably domed lens.

The light influencing body 19 may have a downwardly divergent cross-sectional form, as is indicated in FIG. 5 by broken lines. Through this the emission region of the light influencing body 19 can be increased in acute angle.

FIG. 5 shows a base part construction in modified configuration, wherein the light guides 4 may bear on a base ring plate 14a, from the outer edge or which an outer base ring plate 14b projects to the outside, on which the cooling bodies 11 and if applicable also the outer edge of the base ring plate can lie. The inner edge of the base ring plate 14a can lie on an inner base ring plate 14c which surrounds the light influencing body 19, and can be screwed together with a ceiling plate 22 at least partly covering the light guides 4 and the cooling bodies 11 by means of screws 23 arranged vertically, which can e.g. extend in the spacing region between two light guides 4 neighboring each other. The ceiling disk 22 may have a central hole 24 and it may be arranged at a vertical spacing d from the light guides 4, the height e of which is less than the height of the cooling bodies 11. The hole 24 and the vertical spacing d can used for the passage through of electrical lines 25 to the light-emitting diodes 2.

The luminaire 1 is also suited for emitting light of different colour or light in a particular colour mixture. For this purpose, there can be provided e.g. light diodes 2 which emit light in different colour. Also in this case it is advantageous to provide a light mixing device 16 which makes uniform the transitions between light zones of different colour.

If for example a lesser number of the light guides 4 deliver light of a certain color and a larger number of the light guides 4 deliver a light of other color, it is advantageous to arrange the light guides 4 of lesser number in the center and the light guides 4 of larger number in the peripheral region of the light emission region 5.

1. Luminaire with a plurality of light-emitting diodes in a decentralized arrangement,
comprising a light emission region which is smaller than an arrangement region defined by the totality of the light-emitting diodes.

2. Luminaire according to claim 1, wherein
the light produced by the light-emitting diodes is brought together by light guides having respective light emissions ends to a concentrated light emission region.

3. Luminaire according to claim 2, wherein
a light guide is provided for each light-emitting diode or for each light-emitting diode unit.

4. Luminaire according to claim 1, wherein
the light-emitting diodes and/or the light emission ends of the light guides are arranged respectively in a plane or in two offset planes, which respectively extend approximately horizontally.

5. Luminaire according to claim 1, wherein
the light-emitting diodes on the one hand and the light emission ends of the light guides on the other hand are arranged at different heights, wherein the light emission ends are arranged lower than the light-emitting diodes.

6. Luminaire according to claim 1, wherein
the light-emitting diodes and/or the light emission ends of the light guides are respectively arranged in a row or in two rows running parallel to each other, or are arranged in a round ring form.

7. Luminaire according to claim 1 wherein
the light guides—seen longitudinally of a vertical middle axis of the luminaire—are arranged ray-like.

8. Luminaire according to claim 1, wherein
the light guides extend straight horizontally or arc-shaped downwardly curved.

9. Luminaire according to claim 1, wherein
the light-emitting diodes are arranged outside a reflector and the light guides extend into the reflector.

10. Luminaire according to claim 1, wherein
the light emission ends are distributed on the emission region.

11. Luminaire according to claim 1, wherein
a cooling device is associated with each light-emitting diode or there is associated with the light-emitting diodes a common cooling device.

12. Luminaire according to claim 11, wherein
the cooling device is formed by a common cooling body or by a plurality of cooling bodies, on which the light-emitting diodes are fastened.

13. Luminaire according to claim 12, wherein
the common cooling body is formed ring-like or the cooling bodies are arranged ring-like.

14. Luminaire according to claim 12, wherein
the light-emitting diodes are arranged on upright extending surfaces of the cooling bodies.

15. Luminaire according to claim 12, wherein
the cooling body or bodies.
